(19) United States
(12) Patent Application Publication
(10) Pub. No.: US 2014/0073105 A1
(43) Pub. Date: Mar. 13, 2014

(54) METHOD OF MANUFACTURING SEMICONDUCTOR DEVICE WITH ION IRRADIATION

(71) Applicant: Kabushiki Kaisha Toshiba, Tokyo (JP)

(72) Inventor: Tatsunori ISOGAI, Mie-ken (JP)

(73) Assignee: Kabushiki Kaisha Toshiba, Tokyo (JP)

(21) Appl. No.: 14/019,789

(22) Filed: Sep. 6, 2013

(30) Foreign Application Priority Data
Sep. 7, 2012 (JP) 2012-196951

(51) Int. Cl. H01L 29/66

(52) U.S. Cl. CPC H01L 29/66477
USPC 438/306

(57) ABSTRACT

According to one embodiment, a method of manufacturing a semiconductor device is provided. An impurity layer containing impurity atoms is formed on a semiconductor layer. The impurity layer is then irradiated with first ions having a first energy. Further, the impurity layer is irradiated with second ions having a second energy larger than the first energy.

### CROSS-REFERENCE TO RELATED APPLICATION

This application is based upon and claims the benefit of priority from the prior Japanese Patent Application No. 2012-196951, filed on Sep. 7, 2012, the entire contents of which are incorporated herein by reference.

### FIELD

Embodiments described herein relate generally to a method of manufacturing a semiconductor device with ion irradiation.

### BACKGROUND

In processes for manufacturing a semiconductor device, a beam-line ion implanter is often used to dope a semiconductor with impurities. The beam-line ion implanter has low beam transport efficiency and low productivity in some cases under an implantation condition of low-energy and high-dose. Accordingly, plasma doping which is suitable for low energy and high-dose ion implantation attracts attention.

In the plasma doping, impurity ions contained in plasma are accelerated by a potential difference between the plasma and the semiconductor substrate, and are implanted into the semiconductor substrate. Thus, the plasma doping can simultaneously implant the impurities into the entire surface of the semiconductor substrate exposed to the plasma, which can implement high-dose implantation within a short time.

The plasma doping, however, implants not only desired impurity ions but also other ions existing in the plasma. For example, any of diborane (B₂H₆), phosphine (PH₃) and arsine (AsH₃) which may be used as impurity-containing gas in ion implantation contains hydrogen.

Accordingly, in the plasma, impurity ions of boron (B), phosphor (P) or arsenic (As) and ions of hydrogen are produced by exciting, and these ions are implanted together into the semiconductor substrate. The hydrogen ions have a small-mass and are implanted deeper than the impurity ions, which may cause a bad influence on the properties of a semiconductor device.

### BRIEF DESCRIPTION OF THE DRAWINGS

FIGS. 1A to 1D are schematic cross-sectional views illustrating respective steps of a method of manufacturing a semiconductor device according to a first embodiment.

FIG. 2 is a schematic view illustrating an example of a manufacturing apparatus which is used in the method of manufacturing a semiconductor device.

FIG. 3 is a flowchart showing an operation of the manufacturing apparatus of FIG. 2.

FIGS. 4A to 4E are schematic cross-sectional views illustrating respective steps of a method of manufacturing a semiconductor device according to a second embodiment.

FIGS. 5A to 5D are schematic cross-sectional views illustrating respective steps of a method of manufacturing a semiconductor device according to a third embodiment.

FIGS. 6A to 6B are schematic cross-sectional views illustrating respective processes of manufacturing a semiconductor device according to comparative examples.

### DETAILED DESCRIPTION

According to one embodiment, a method of manufacturing a semiconductor device is provided. An impurity layer containing impurity atoms is formed on a semiconductor layer. The impurity layer is then irradiated with first ions having a first energy. Further, the impurity layer is irradiated with second ions having a second energy larger than the first energy.

Hereinafter, further embodiments will be described with reference to the drawings. In the drawings, the same reference numerals denote the same or similar portions respectively.

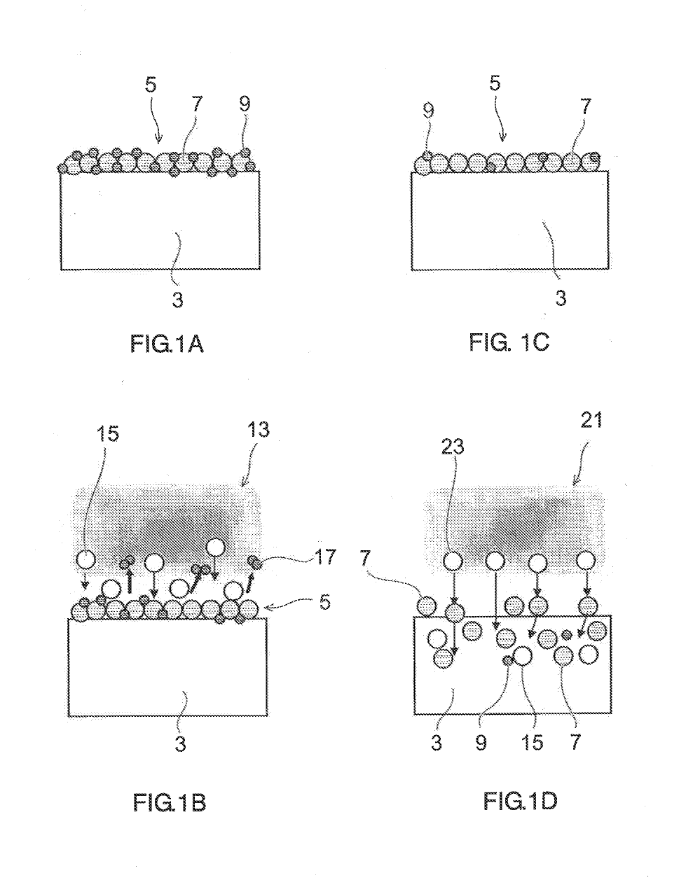

A first embodiment will be described with reference to FIGS. 1A to 1D. FIGS. 1A to 1D are schematic cross-sectional views illustrating steps of a method of manufacturing a semiconductor device according to the first embodiment.

In the method of manufacturing a semiconductor device according to the first embodiment, an impurity layer containing impurity atoms is formed on a substrate. The impurity layer is irradiated with first ions having a first energy and is then irradiated with second ions having a second energy larger than the first energy.

FIG. 1A illustrates a first step of forming an impurity layer 5 on a substrate 3. The impurity layer 5 is a layer containing impurities. The impurity layer 5 contains impurity atoms 7 which are to be introduced into the substrate 3. The substrate 3 may be a semiconductor substrate, a semiconductor substrate in which a well region is formed, or a substrate on which a semiconductor layer or a semiconductor film is formed.

The impurity layer 5 is formed by PCVD (plasma-assisted chemical vapor deposition), for example. The impurity atoms 7 can be atoms of at least one element selected from boron (B), carbon (C), phosphor (P), arsenic (As), antimony (Sb) or indium (In), for example.

In the case of using phosphor (P) as the impurity atoms 7, the impurity layer 5 is deposited by PVCD using phosphine (PH₃) as a raw material, for example. As illustrated in FIG. 1A, the impurity layer 5 deposited on the substrate 3 contains hydrogen atoms 9 and phosphor atoms as the impurity atoms 7. The hydrogen atoms 9 are included in the impurity layer 5, in a state bonding with phosphor atoms (P—H bonds) or in a state of hydrogen molecules, for example.

FIG. 1B illustrates a second step of irradiating the impurity layer 5 with ions 15 as first ions having a first energy. A gas which contains atoms of at least one element selected from helium (He), neon (Ne), argon (Ar), krypton (Kr) or xenon (Xe), for example, is excited to form a plasma 13, and ionizes the atoms. The impurity layer 5 is irradiated with the ions 15 having the first energy by exposing the substrate 3 to the plasma 13, by creating a potential difference between the plasma 13 and the substrate 3, or by the both.

In the above process, as illustrated in FIG. 1B, the bonds between the impurity atoms 7 and hydrogen atoms 9 are broken by collision with the ions 15, and the hydrogen atoms 9 form hydrogen molecules 17 and separate from the impurity layer 5. The ions 15 have energy enough to collide with the hydrogen atoms 9 and break the bonds between the impurity atoms 7 and hydrogen atoms 9. It is desirable that the hydrogen atoms which separate by the collision with the ions 15 are prevented from penetrating into the substrate 3. Accordingly, the first energy is such a level as to break the bonds between the impurity atoms 7 and hydrogen atoms 9 but not to give the hydrogen atoms enough kinetic energy to allow the hydrogen atoms to penetrate into the substrate 3. Furthermore, it is desirable that the first energy is not enough to sputter-etch the impurity layer 5.

The plasma 13 has a higher potential than that of the substrate 3. In the case of a parallel-plate plasma apparatus which is often used in semiconductor manufacturing, for example, the potential difference between the plasma 13 and substrate 3 is about several tens volts in many cases. Accordingly even when the substrate 3 is not subjected to bias voltage, positive monovalent ions produced in the plasma 13 have an energy of about several tens eV. P—H bonds, B—H bonds and As—H bonds have energy of several eV and can be easily broken by ion irradiation with an energy of several tens eV. On the other hand, ions having a low energy not more than about 100 eV including low-mass hydrogen ions do not penetrate deeply into the semiconductor. Accordingly, it is desirable that the first energy ranges from several tens to a hundred eV.

FIG. 1C illustrates a state which occurs after the irradiation of the impurity layer 5 with the ions 15 having the first energy is completed. The number of the hydrogen atoms 9 which are bonded to the impurity atoms 7 in the state illustrated in FIG. 1C is smaller than that just after the impurity layer 5 is formed as illustrated in FIG. 1A.

FIG. 1D illustrates a third step of irradiating the impurity layer 5 with ions 23 as second ions having a second energy larger than the first energy, and of introducing the impurity atoms 7 into the substrate 3. A gas containing atoms of at least an element selected from He, Ne, Ar, Kr or Xe, for example, is excited to form a plasma 21, and then a predetermined potential difference is given between the substrate 3 and plasma 21. The ions 23 excited in the plasma 21 are accelerated by the above method and are projected onto the impurity layer 5.

The second energy is energy of the ions 23 accelerated by the potential difference between the substrate 3 and plasma 23 and is larger than the first energy. The impurity atoms 7 which collide with the ions 23 and obtain kinetic energy penetrate into the substrate 3. Simultaneously, the hydrogen atoms 9 are given kinetic energy and penetrate into the substrate 3. However, the irradiation with the ions 15 illustrated in FIG. 1B reduces the amount of hydrogen atoms, and a small amount of hydrogen atoms 9 penetrates into the substrate 3. Moreover, at least some of the ions 23 are implanted into the substrate 3. Thus, it is desirable that the ions 23 are the above-mentioned inactive atoms which do not form carriers in the semiconductor but may be atoms capable of constituting the substrate 3, such as silicon (Si) or germanium (Ge).

The ions 23, 15 may be ions of the same element or different elements. In other words, the gas excited to form the plasma 21 may be the same or different from the gas excited to form the plasma 13. Moreover, each of the excitation gases may contain elements other than hydrogen.

The plasma doping carried out in the above manufacturing process is so-called plasma recoil implantation. In the above process, a thin layer containing impurity atoms is deposited on the surface of the substrate, and high-energy ions generated in the plasma are caused to collide with the impurity atoms to introduce the impurity atoms into the substrate. Accordingly, the plasma recoil implantation can reduce the amount of hydrogen atoms which are introduced into the thin layer, compared with a process of dissociating raw-material gas containing impurities in the plasma and implanting the ionized impurity atoms. Moreover, in the embodiment, the impurity layer 5 formed on the substrate 3 is irradiated with the ions 15 of low energy so that the hydrogen atoms 9 are removed from the impurity layer 5. Accordingly, the amount of hydrogen atoms 9 introduced into the substrate 3 can be significantly reduced.

Another method to remove hydrogen introduced in the impurity layer 5 is heat treatment of the substrate 3 on which the impurity layer 5 is formed. Heating the impurity layer 5 can dissociate the hydrogen atoms 9 bonded to the impurity atoms 7 and release the hydrogen atoms 9 as hydrogen molecules. The heating is performed at a temperature of not less than 200° C., for example. On the other hand, in a step of introducing impurities into a semiconductor substrate, ions are selectively implanted by covering the surface of the semiconductor substrate partially with a resist mask, in many cases. The resist mask used in such a step can deform or decompose at temperatures larger than 100° C. Accordingly, the maximum temperature to be set at a heat treatment of the semiconductor substrate on which the resist mask is formed is limited to about 100° C., and the hydrogen atoms cannot be adequately removed from an impurity layer.

In the embodiment, the impurity layer 5 is irradiated with the ions 15 having the first energy, and hydrogen atoms contained in the impurity layer 5 can be efficiently removed even when the substrate temperature is not larger than 100° C. Accordingly, the first embodiment is also applicable to a substrate on which a resist mask is formed.

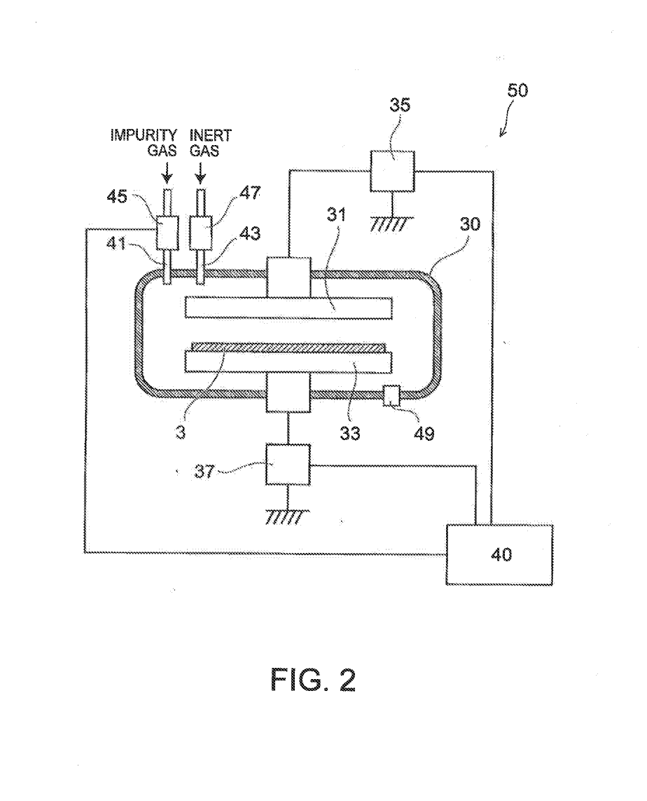

FIG. 2 is a schematic view illustrating an example of a manufacturing apparatus 50 which can be used in the above method of manufacturing a semiconductor device. The manufacturing apparatus 50 is a parallel-plate plasma processing apparatus, and includes a chamber 30, an upper electrode 31 and a lower electrode 33. The upper and lower electrodes 31 and 33 are located facing each other within the chamber 30. The lower electrode 33 serves as a substrate holder.

The inside of the chamber 30 is evacuated through an exhaust port 49 by a vacuum pump (not shown) provided outside of the chamber 30. The upper electrode 31 is connected to an RF power supply (RF power source) 35 as a first high-frequency power supply, and the lower electrode 33 is connected to an RF power supply (RF power source) 37 as a second high-frequency power supply.

The RF power supply 35 forms a plasma between the upper and lower electrodes 31 and 33. The RF power supply 37 is a bias power supply producing a potential difference between the plasma and the substrate 3 placed on the lower electrode 33.

The chamber 30 is provided with gas ports 41, 43 through which raw-material gas containing impurities and inert gas are introduced from the outside, respectively. The raw-material gas is introduced from the gas port 41 through a mass flow controller (hereinafter, referred to as an MFC) 45, and the inert gas is introduced from the gas port 43 through an MFC 47.

The manufacturing apparatus 50 is further provided with a controller 40 for controlling the RF power supplies 35, 37 and the MFCs 45 and 47.

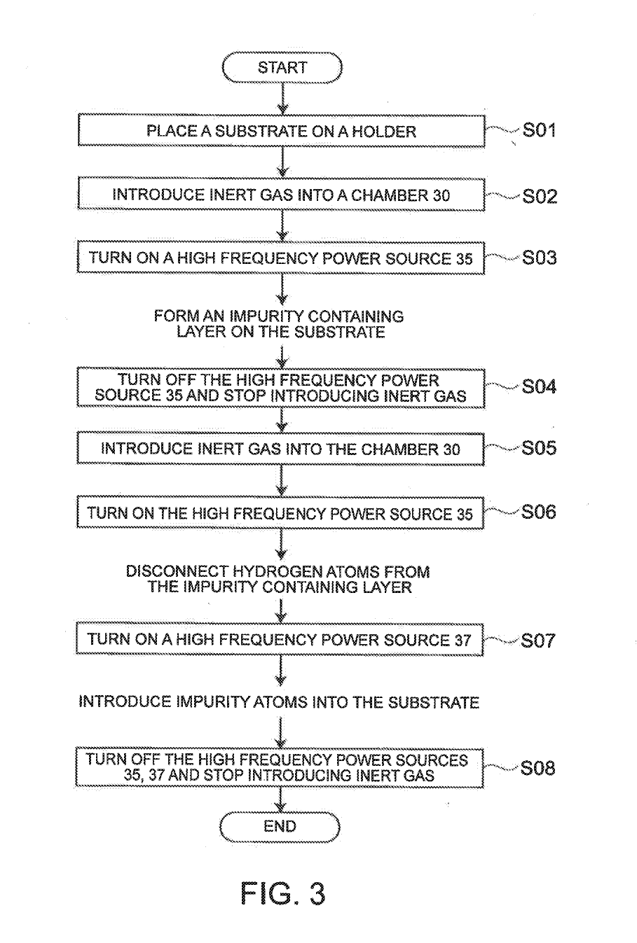

FIG. 3 is a flowchart showing an operation of the manufacturing apparatus 50. The manufacturing apparatus 50 performs a step of forming an impurity layer 5, a step of irradiating the impurity layer 5 with ions 15 having a first energy, and a step of irradiating the impurity layer 5 with ions 23 having a second energy successively, which are illustrated in FIGS. 1A to 1D.

The substrate 3 is delivered into the chamber 30 of FIG. 2 and is placed on the lower electrode 33 (step S01). Subsequently, the MFC 45 is turned on to introduce the raw-material gas containing impurities from the gas port 41 into the chamber 30 (step S02).

The inside of the chamber 30 is adjusted to a predetermined pressure, and the RF power supply 35 is turned on (step S03). Turning on the RF power supply 35 causes high-frequency discharge between the upper and lower electrodes 31 and 33 to form plasma. The impurity ions dissociated in the plasma deposit on the surface of the substrate 3 to form the impurity layer 5.

When the impurity layer 5 reaches a predetermined thickness, the RF power supply 35 and MFC 45 are turned off (step S04). Specifically, the time period necessary to make the impurity layer 5 reach a predetermined thickness is calculated from the speed of deposition of the impurity layer 5, and turning on and off of the RF power supply 35 is controlled based on a calculated time period. After the impurity layer 5 is formed, the inside of the chamber 30 is evacuated to remove the raw-material gas containing the impurities.

Then, the MFC 47 is turned on to introduce inert gas into the chamber 30 from the gas port 43 (step S05). The pressure within the chamber 30 is then adjusted to a predetermined value, and the RF power supply 35 is turned on (step S06).

By turning on the RF power supply 35, a plasma is produced between the upper and lower electrodes 31 and 33, and the impurity layer 5 formed on the substrate 3 is exposed to the plasma. At this time, the RF power supply 37 is off, and the impurity layer 5 is irradiated with ions accelerated by the potential difference between the plasma and the substrate 3. The potential difference is several tens volts. The ion irradiation causes the hydrogen atoms to separate from the impurity layer 5. In the above step, the RF power supplies 35, 37 may be simultaneously turned on to control the potential difference between the plasma and the substrate 3 so as to set to a value of not more than 100 V.

The RF power supply 37 is turned on to increase the potential difference between the plasma and the substrate 3 at a predetermined time period after the RF power supply 35 is turned on as described above (step S07). By turning on the RF power supply 37, the impurity layer 5 is irradiated with the ions having increased energy so that the impurity atoms 7 can be knocked on into the substrate 3.

After a predetermined time period, the RF power supplies 35, 37 are both turned off, and the MFC 47 is also turned off to shut off the inert gas (step S08).

The time period for irradiating the impurity layer 5 with the low-energy ions is set enough to remove the hydrogen atoms but so as not to reduce the throughput of the apparatus. The time period which ranges after the RF power supply 35 is turned on and until the RF power supply 37 is turned on can be set not less than 0.5 seconds and not more than 10 seconds, for example.

The above process can be automatically controlled by a controller 40 provided with a sequencer or a program executing the steps S01 to S08. The controller 40 can control the above process by carrying out on/off control of the RF power supplies 35, 37 and the MFCs 45, 47. The controller 40 may be connected to a vacuum valve (not shown) connected to the chamber 30 so as to control the pressure of the chamber 30.

According to the above example, the plasma formed between the upper electrode 31 and the lower electrode 33 is maintained throughout the steps S06 to S08. Thus, the element of the low-energy ions projected onto the impurity layer 5 may be the same as that of the high-energy ions but is not limited to the case. The RF power supply 35 may be turned off when the step S06 is completed. After a gas for exciting the plasma is replaced with another, the RF power supplies 35, 37 are simultaneously turned on in the step S07. In this case, the element of the low-energy ions may be different from that of the high-energy ions.

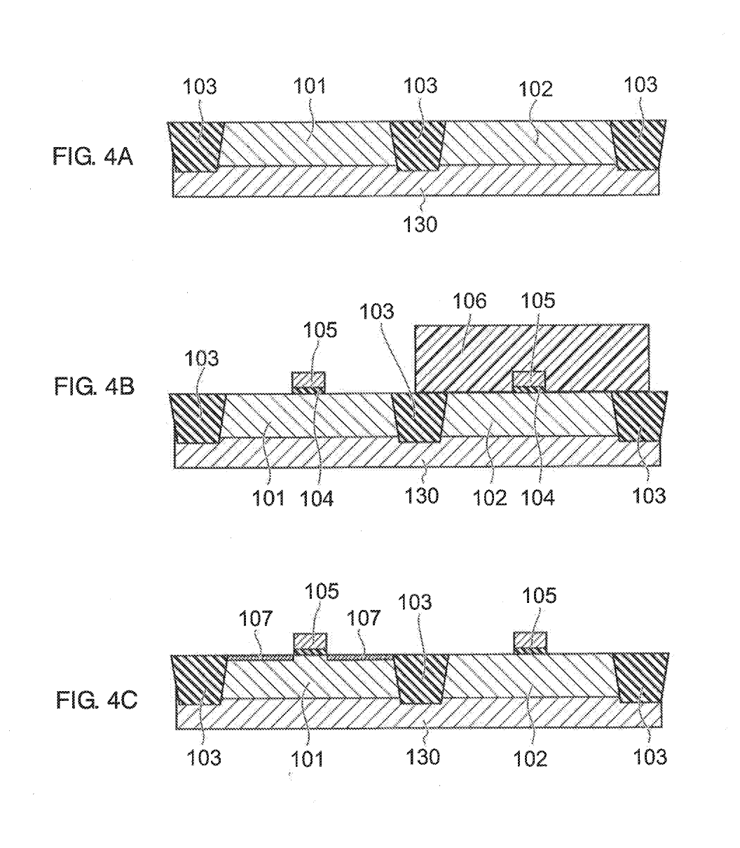

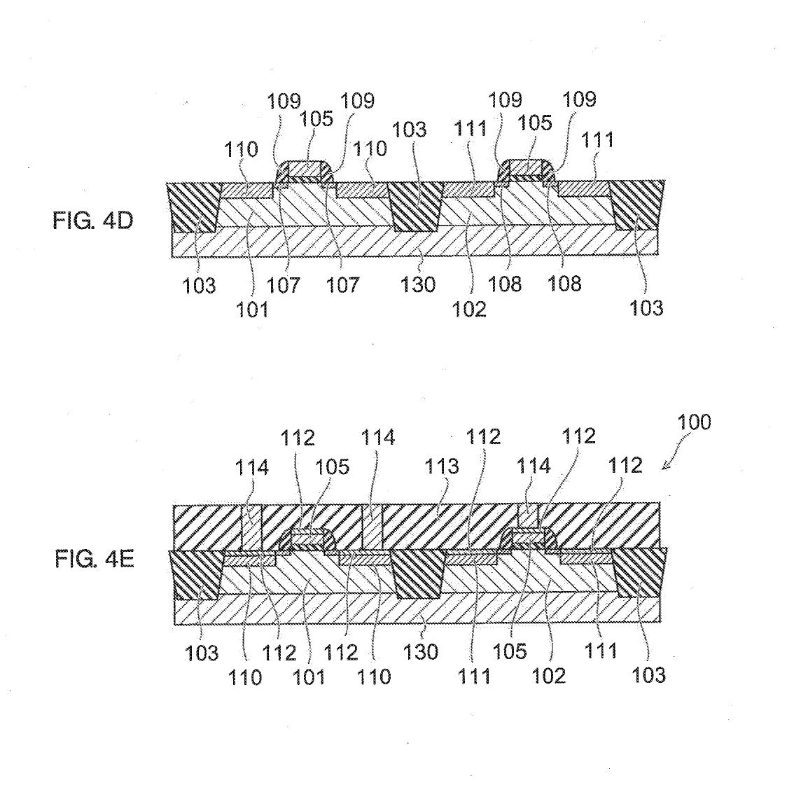

FIGS. 4A to 4E are schematic and partial cross-sectional views illustrating steps of a method of manufacturing a semiconductor device according to a second embodiment. The semiconductor device to be manufactured is a MOS (metal oxide semiconductor) transistor having an extension region, for example.

As illustrated in FIG. 4A, an n-type well 101 and a p-type well 102 are selectively formed as impurity diffusion regions in a surface portion of a semiconductor substrate 130.

The semiconductor substrate 130 is a silicon single-crystal substrate having a plane direction (100), for example. The material of the semiconductor substrate 130 is not limited to silicon and may be germanium, silicon germanium (SiGe), silicon carbide (SiC) or gallium arsenic (GaAs). Alternatively, the semiconductor substrate 130 may be a SOI (silicon on insulator) substrate.

The conductivity type and the impurity concentration of the semiconductor substrate 130 are adjusted by ion implantation and subsequent heat treatment. Specifically, a proper amount of n-type impurities are ion-implanted into the n-type well 101 composing a P-type MOS transistor, and an n-type region with a predetermined impurity concentration is formed. A proper amount of p-type impurities composing an N-type MOS transistor is ion-implanted into the p-type well 102, and a p-type region with a predetermined impurity concentration is formed.

Subsequently, STI (shallow trench isolation) is formed on the semiconductor substrate 130 in order to obtain element isolation between the n-type well 101 and the p-type well 102. Specifically, trenches are formed in the semiconductor substrate 130 by RIE (reactive ion etching), and an insulating film mainly composed of silicon oxide film is formed on the entire surface of the semiconductor substrate 130 including the trenches. Then, the insulating film formed on the surface is partially removed by CMP (chemical mechanical polishing) so as to flatten the surface. When the surface is flattened, element isolation regions 103 which are composed of the trenches buried with the insulating film are formed.

The surface of the semiconductor substrate 130 is cleaned, and a gate insulating film 104 is formed. The gate insulating film 104 can be composed of silicon oxide film formed by heat oxidation or plasma oxidation. Alternatively, the gate insulating film 104 can be made of nitride oxide film or high-k film which is formed by performing heat treatment or plasma treatment in nitrogen-contained gas.

Subsequently, a polycrystalline silicon film for forming the gate electrodes 105 is formed on the gate insulating film 104. The polycrystalline silicon film is subjected to ion implantation and heat treatment to have a conductive property. Specifically, in order to regulate the threshold voltage of the MOS transistor, the gate electrode of the N-type MOS transistor is designed to have n-type conductivity, and the gate electrode of the p-type MOS transistor is designed to have p-type conductivity. In order to reduce the gate resistance, the polycrystalline silicon film may be replaced with metallic film or multi-layer film composed of polycrystalline silicon and metal stacked on each other.

Specifically, a resist mask (not shown) is formed on the substrate 130 using photolithography. A circuit pattern is then transferred onto the resist mask, and the polycrystalline silicon film is processed by RIE. As illustrated in FIG. 4B, the gate electrodes 105 are formed on the n-wells 101 and the p-type wells 102 via the gate insulating film 104.

Then, extension regions are formed using the plasma doping. As illustrated in FIGS. 4B and 4C, the p-type well 102 is covered with a resist (pattern) 106, and p-type extension regions 107 are formed on the surface of the n-type well 101.

In a first step to form the extension regions 107, the semiconductor substrate 130 on which the resist 106 is formed is introduced into the plasma doping apparatus, and an impurity layer containing boron (B) as p-type impurities is formed as the first impurity layer by PCVD. For example, a raw-material gas containing argon gas and 10% diborane gas (B₂H₆) diluted with helium which are mixed at a ratio of 20:1 is introduced into the chamber, and is excited to form a plasma at a pressure of 0.5 Pa. The frequency of a RF power supply for producing plasma is about 13.56 MHz, for example, and the output of the RF power supply is adjusted in a range from 500 to 4000 W.

The thickness of the impurity layer is properly adjusted corresponding to a target dose amount. The impurity layer is made thick when the target dose amount is large, and the impurity layer is made thin when the target dose amount is small. A high frequency power does not need to be supplied to the semiconductor substrate 130 in the step of forming the impurity layer. In this case, electric power of several tens W may be applied to the substrate to adjust the potential difference between the plasma and the semiconductor substrate 130 for the purpose of raising the quality of the impurity layer. In either case, the impurity layer contains boron (B) and hydrogen atoms dissociated from diborane.

Subsequently, low-energy ion irradiation is performed in a second step. The gas for exciting plasma is changed to argon gas and is excited to form a plasma at a pressure of 0.5 Pa. In this case, the high-frequency output of the RF power supply is also set in a range from 500 to 4000 W, and the substrate 130 is irradiated with argon (first ions) ionized in the plasma. The process of changing the plasma excitation gas may include some waiting time in order to ensure discharge of hydrogen remaining in the chamber. Moreover, high-frequency power may be applied to the semiconductor substrate 130 to bias the semiconductor substrate 130 with respect to the plasma. In this case, it is desirable that the potential difference between the plasma and the semiconductor substrate 130 is not more than 100 V from the viewpoint of preventing the impurity layer from being etched and preventing unintended knock-on of hydrogen atoms included in the impurity layer.

The irradiation with ions which are accelerated by an appropriate bias can efficiently supply energy to the surface of the impurity layer. Accordingly, hydrogen atoms can be removed from the impurity layer by irradiation with low-energy ions for about 5 seconds. On the other hand, it is necessary to optimize the ion irradiation time so that introduction of ion irradiation of low energy cannot cause reduction in productivity. It is desirable that the ion irradiation time is set within 10 seconds.

The plasma excitation gas can be an inactive noble gas selected from helium, neon, argon, krypton or xenon, for example. The most desirable gas is argon in terms of manufacturing cost.

In a third step, knock-on for introducing boron (B) as the p-type impurities into the n-type well 101 is performed. Specifically, the impurity layer containing boron is irradiated with high energy ions for implanting boron into the substrate.

The plasma excitation gas is argon gas in succession to the second step. The pressure within the chamber is set to 0.5 Pa, and a high-frequency power in a range from 500 to 4000 W is supplied to produce a plasma. In this case, the plasma produced in the second step may be maintained and be used. Simultaneously, biasing power is supplied to the semiconductor substrate 130 so that the potential difference between the plasma and the semiconductor substrate 130 is several hundred V to several kV. The supply of the biasing power excites ions (second ions) to a higher energy level than the ions in the second step. It is desirable that the frequency of the high-frequency power supplied to the semiconductor substrate 130 is in a range from several 100 kHz to 2 MHz.

The larger the potential difference between the plasma and the semiconductor substrate 130, the higher energy the ions indicate and the deeper the knocked-on impurities are implanted. The ion irradiation is performed, until all of the impurities contained in the impurity layer which is deposited on the surface of the n-type well 101 are introduced into the n-type well 101 so that a plasma doping is completed.

The first to third steps are desirably performed successively within the same chamber. Moreover, the plasma to be produced in the third step uses the same excitation gas as that employed in the second step, desirably. In this case, the transition from the second step to the third step can be performed by changing the biasing power to be supplied to the substrate. This method can increase the throughput of the plasma doping apparatus and can increase the manufacturing efficiency.

Then, the resist 106 is removed as illustrated in FIG. 4C, and the semiconductor substrate 130 is heat-treated. The heat treatment activates boron (B) as the p-type impurities introduced into the n-type well 101, and forms p-type extension regions 107 near the surface of the n-type well 101.

The above heat treatment can be rapid thermal annealing (RTA) at a maximum temperature of 900 to 1000° C., for example. Alternatively, the heat treatment may be a process of making an ion-implanted layer amorphous by irradiation with high-energy ions and then heating the ion-implanted layer to perform solid epitaxial growth. The process can activate the impurities at comparatively low temperature and is effective when the gate electrodes are made of metal having low heat resistance, for example. The heat treatment may be performed using other activation annealing such as flash lamp annealing (FLA) or laser spike annealing (LSA).

Then, the n-type well 101 is covered with a resist, and the p-type well 102 is plasma-doped with n-type impurities so that n-type extension regions 108 are formed. The n-type extension regions 108 can be formed by the same way as the p-type extension regions 107 are formed except that a different kind of impurities is introduced. The raw-material gas containing impurities can be phosphine (PH₃) or arsine (AsH₃) instead of diborane (B₂H₆).

After a sidewall 109 of an insulating material is formed on a side surface of each gate electrode 105, source/drain regions 110, 111 are formed as illustrated in FIG. 4D. In this case, the p-type source/drain regions 110 are formed by ion-implanting the p-type impurities into the n-type well 101 selectively. On the other hand, the n-type source/drain regions 111 are formed by ion-implanting n-type impurities into the p-type well 102 selectively.

The source/drain regions 110, 111 can be formed using plasma doping. In the case, it is necessary to form the source/drain regions 110, 111 deeper than the extension regions and to set the impurity concentration of the source/drain regions 110, 111 higher than the extension regions. Accordingly, the thickness of the impurity layer and the substrate bias are properly adjusted according to the purpose.

In the case of forming the source/drain regions 110, 111, the thickness of the impurity layer formed in a first step as the second impurity layer is set four to five times the thickness of the impurity layer in forming the extension regions. Furthermore, the impurity layer is irradiated with low-energy ions (third ions) in a second step. The impurity layer is then irradiated with high-energy ions (fourth ions) with the substrate bias set five to ten times the bias in the case of forming the extension regions, in a third step. Accordingly, the source/drain regions 110, 111 can be formed deeper than the extension regions and have higher impurity concentration.

In the case of forming the source/drain regions, the substrate bias in the third step (introducing impurities into the semiconductor substrate 130) is larger than that in the case of forming the extension regions. This enables the energy of excited ions (fourth ions) larger than those of the ions (first and second ions) used in the case of forming the extension regions. Accordingly, the energy of the fourth ions is larger than the energy of the second and third ions. The fourth ions may be atoms of the same kind as that of the third ions.

Subsequently, as illustrated in FIG. 4E, interlayer insulating film 113 is formed on the n-type well 101 and the p-type well 102, and contact plugs 114 which come into contact with the source/drain regions 110, 111 and gate electrodes 105 are formed.

Before the interlayer insulating film 113 is formed, silicide regions 112 are formed on the upper surfaces of the source/drain regions 110, 111 and gate electrodes 105. Forming the silicide regions 112 reduces parasitic serial resistance between the contact plugs 114 and the respective source/drain regions and gate electrodes 105.

The silicide regions 112 can be made of nickel silicide, cobalt silicide, or titanium silicide. The contact plugs 114 are made of tungsten (W), for example. Barrier metal layers (not-shown) may be formed respectively between the silicide regions 112 and interlayer insulating film 113, after the silicide region 112 is formed and before the interlayer insulating film 113 is formed. The barrier metal layers may be composed of laminated films of titanium (Ti) and titanium nitride (TiN).

In the embodiment, extension regions 107, 108 located in shallow positions from the surfaces are formed on both sides of each gate electrode 105. In order to forming the extension regions 107, 108 with a beam-line ion implantation apparatus, a long implantation time is required, which reduces the throughput. On the other hand, the embodiment which uses plasma doping can increase the throughput and increase the productivity. Furthermore, introduction of the hydrogen atoms into the substrate can be prevented by performing the low-energy ion irradiation in the process of plasma doping.

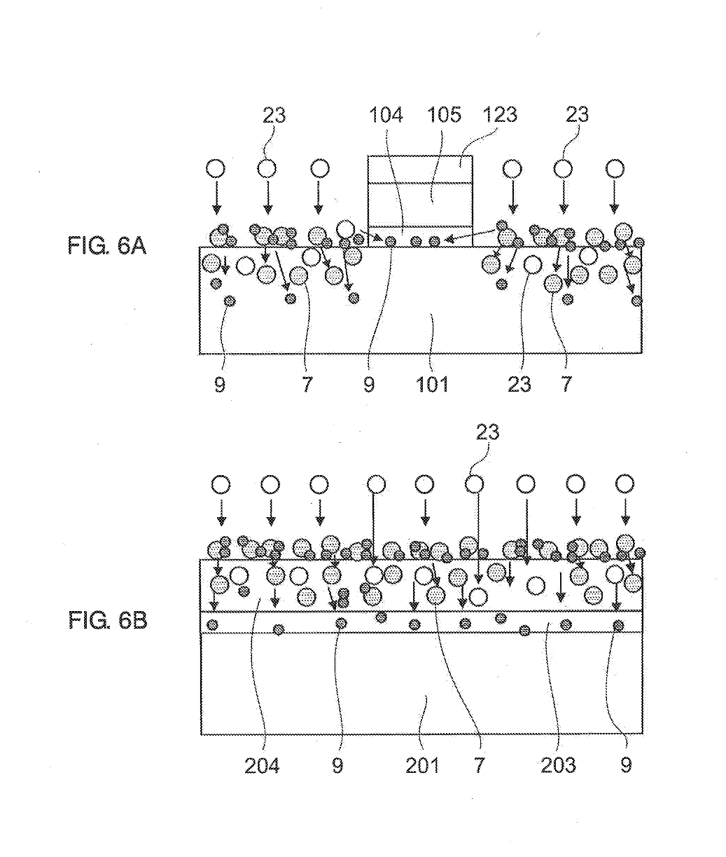

FIG. 6A is a schematic cross-sectional view illustrating a process of manufacturing a semiconductor device according to a comparative example. In this comparative example, low-energy ion irradiation as that in the second step is not performed, and an impurity layer from which hydrogen atoms are not removed is irradiated by high-energy ions 23. Since the low-energy ion irradiation is not performed, the amount of hydrogen atoms 9 implanted into an n-type well 101 is larger than that of the embodiment as illustrated in FIG. 6A. Moreover, the amount of hydrogen atoms 9 implanted into the gate insulating film 104 is not negligible.

Even if a hard mask of a silicon nitride film 123 is formed on a gate electrode 105 to prevent implantation of impurities into the gate electrode 105, it is difficult to prevent the hydrogen atoms 9 from penetrating into the gate insulating film 104 through the side surface of the gate electrode 105, for example. The hydrogen atoms 9 implanted into the gate insulating film 104 can reduce the reliability of a MOS transistor composed of the gate insulating film 104.

In the method of manufacturing a semiconductor device according to the second embodiment, plasma doping can increase the productivity while preventing hydrogen atoms from being implanted into the gate insulating film 104, which increases the reliability of the MOS transistor.

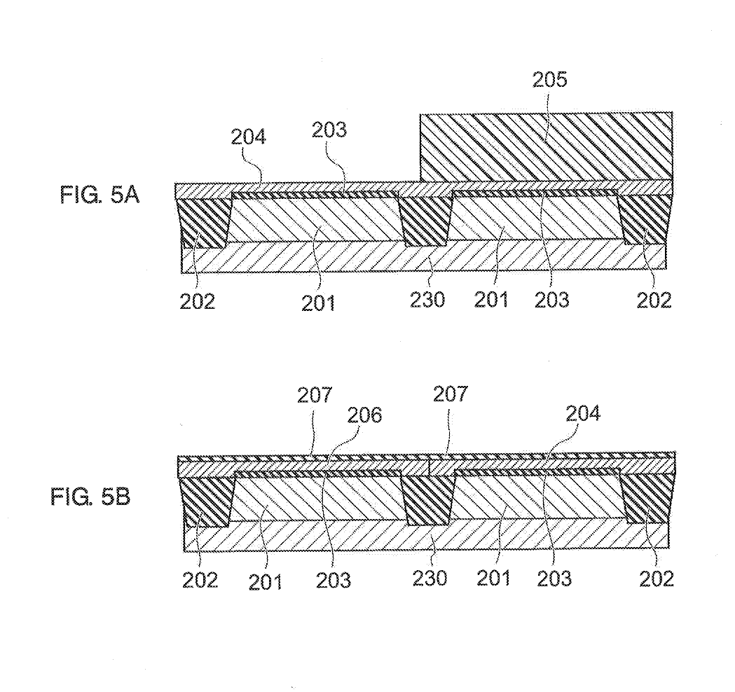

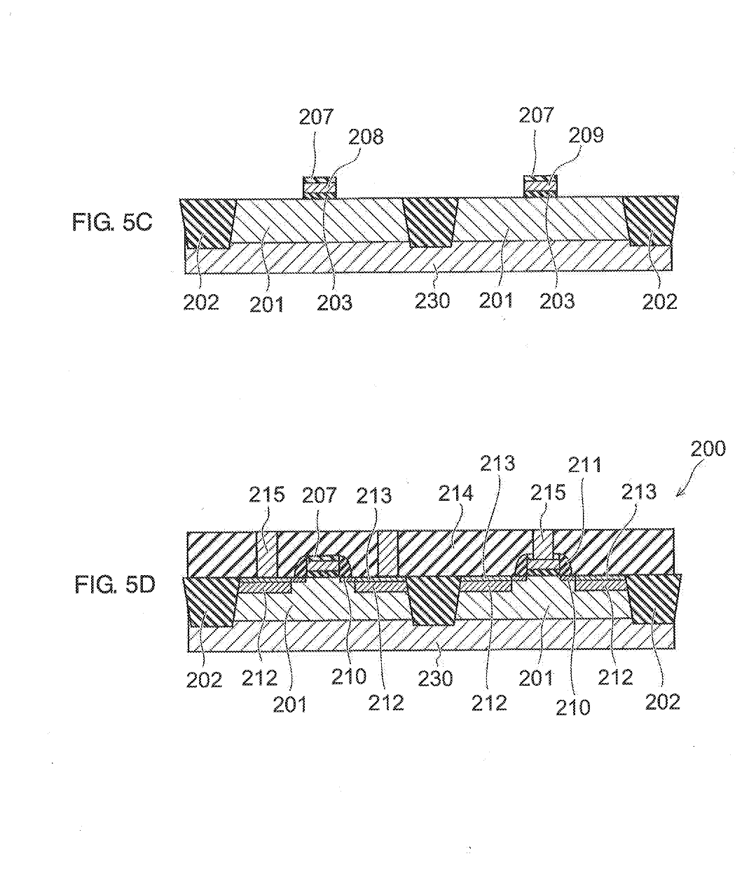

A method of manufacturing a semiconductor device according to a third embodiment will be described with reference to FIGS. 5A to 5D. FIGS. 5A to 5D illustrate a partial cross section of a substrate in the respective steps of the method schematically.

The second embodiment shows an example in which plasma doping is used in introducing impurities into a substrate composing a MOS transistor. In the third embodiment, plasma doping is applied to introduction of impurities into polycrystalline silicon to form gate electrodes.

In a MOS transistor, a gate electrode of an n-type MOS transistor is made of n-type polycrystalline silicon, and a gate of a p-type MOS transistor is made of p-type polycrystalline silicon. However, the configuration of a gate electrode of a MOS transistor is not limited to the above. Some MOS transistors have another type of gate electrode, from the viewpoint of optimizing the threshold voltage and ensuring the reliability of a gate insulating film, for example. The third embodiment will be described using examples in which gate electrodes of n-type polycrystalline silicon and p-type polycrystalline silicon are made respectively in a process of manufacturing an n-type MOS transistor. A p-type MOS transistor can be formed in the same substrate in which a n-type MOS transistor is formed.

As illustrated in FIG. 5A, p-type well regions 201 are formed in a semiconductor substrate 230 as impurity diffusion regions so as to be isolated by element isolation regions 202 having a STI structure. Gate insulating films 203 are formed on the respective p-type well regions 201. Moreover, a p-type polycrystalline film 204 having a thickness of 75 to 200 nm is formed as a semiconductor film on the entire surface of the semiconductor substrate 230 including the surface of the gate insulating films 203. A polycrystalline silicon film for forming the p-type polycrystalline silicon film 204 is formed using low pressure CVD, for example. Alternatively, the polycrystalline silicon film may be formed by forming an amorphous silicon film and then by performing heat treatment for the amorphous silicon film.

Introduction of p-type impurities into the polycrystalline silicon film may be performed by adding diborane gas in a deposition process of polycrystalline silicon of a low pressure CVD and using boron (B) as p-type impurities for doping, for example. Alternatively, introduction of p-type impurities into a polycrystalline silicon film may performed by forming an intrinsic polycrystalline silicon without impurities and then by using beam line-type ion implantation or plasma doping so as to dope with p-type impurities.

In the case of using plasma doping to introduce p-type impurities into polycrystalline silicon film, first to third steps which are the same as those of the second embodiment are performed. Specifically, in the first step, a first impurity layer (not-shown) containing p-type impurities is formed on the polycrystalline silicon film 204 formed by the above process. Subsequently, the first impurity layer is irradiated with first ions as low-energy ions to reduce hydrogen atoms contained in the first impurity layer, in the second step. In the third step, the first impurity layer is irradiated with second ions having higher energy than the first ions, and the p-type impurities are introduced into the polycrystalline silicon film 204. The second ions may be ions obtained by exciting atoms of the same type as that of the first ions.

Then, so-called counter-doping is performed to invert the p-type polycrystalline silicon film 204 to n-type polycrystalline film partially. For the counter-doping, n-type impurities with a higher concentration than the p-type impurities contained in the p-type polycrystalline silicon layer 204 are introduced. It is desirable that the n-type impurities are phosphor (P), which has a high activation ratio and a high thermal diffusivity, for example.

As illustrated in FIG. 5A, the region where the conduction type is not to be inverted in the p-type polycrystalline silicon film 204 is previously covered with resist 205, the plasma doping is used to introduce phosphor (P) as the n-type impurities. First to third steps which are same as those used in the second embodiment are carried out to introduce the n-type impurities into the polycrystalline silicon film.

Specifically, a second impurity layer (not-shown) containing n-type impurities is formed on the p-type polycrystalline silicon film 204 in the first step. The second impurity layer is an impurity layer formed by changing the raw-material gas from diborane to phosphine so as to contain an enough amount of phosphor to invert the p-type polycrystalline silicon film 204 to the n-type. In the second step, the second impurity layer containing phosphor is irradiated with third ions as low-energy ions to remove hydrogen atoms. Subsequently, the second impurity layer is irradiated with fourth ions having higher energy than the third ions to introduce the phosphor as the n-type impurities into the p-type polycrystalline silicon film 204. Desirably, the bias voltage of the substrate applied to produce the fourth ions is adjusted so that the phosphor reaches a certain degree of depth for the purpose of preventing the phosphor from diffusing outward in the subsequent heat treatment. The fourth ions may be ions obtained by exciting atoms of the same type as that of the third ions.

Then, after the resist 205 is removed, heat treatment is performed in a range of temperature from 850 to 950° C. for several tens seconds to several minutes. By the heat treatment, phosphor (P) is diffuses and electrically activated. Moreover, the heat treatment partially inverts the p-type poly crystalline silicon film 204 to an n-type polycrystalline silicon film 206. Subsequently, silicon nitride film 207 is formed to a thickness of 50 to 100 nm as a hard mask as illustrated in FIG. 5B.

As illustrated in FIG. 5C, gate electrodes 208, 209 are formed by the following method. For example, a resist pattern (not-shown) for processing gate electrodes is formed by photolithography, and the silicon nitride film 207 is patterned with the resist pattern as a mask. The p-type polycrystalline silicon films 204 and the n-type polycrystalline silicon film 206 are anisotropically etched by RIE to form the gate electrodes 208, 209. The p-type polycrystalline silicon films 204 and the n-type polycrystalline silicon film 206 may be etched simultaneously but may be individually etched under different conditions corresponding to the respective conductivity types because the etching rate of polycrystalline silicon depends on the conduction type.

As illustrated in FIG. 5D, extension regions 210 and a sidewall 211 of insulating film are formed on both sides of each of the gate electrodes 208, 209, and then source/drain regions 212 are formed. The method of forming the above elements is same as the method shown in the second embodiment. In order to form a N-type MOS transistor, in the third embodiment, the extension regions 210 and source/drain regions 212 are n-type conductivity, and the extension regions 210 are formed by plasma doping using phosphine or arsine as the raw-material gas.

Since the silicon nitride film 207 is formed directly on the p-type gate electrodes 209, the n-type impurities are not introduced into the p-type gate electrode 209 at the process of forming the extension regions 210 and the source/drain regions 212. Accordingly, the p-type gate electrode 209 is not inverted to the n-type.

Subsequently, silicide regions 213, interlayer insulating films 214, and contact plugs 215 are formed on the upper surface of the source/drain regions 212 in a manner similar to the second embodiment. This is performed to complete the process of manufacturing a semiconductor device 200 including n-type MOS transistors.

In the third embodiment, the silicon nitride film 207 is formed as the hard mask. Accordingly, the upper surfaces of the gate electrodes 208 and 209 are not silicided. The upper surfaces of the gate electrodes 208, 209 may be silicided after the hard mask is removed, as another example.

The third embodiment uses the plasma doping on introducing n-type impurities into the p-type polycrystalline silicon film 204 and forming the n-type extension regions 210 and n-type source/drain regions 212. Use of the plasma doping can increase the productivity of the semiconductor device 200. Furthermore, introducing low-energy ion irradiation into the plasma doping can reduce the amount of hydrogen atoms to be introduced.

FIG. 6B is a schematic cross-sectional view illustrating a process of doping into polycrystalline silicon in manufacturing a semiconductor device according to another comparative example. In this comparative example, an impurity layer which is not subjected to low-energy ion irradiation and from which hydrogen atoms are not removed is irradiated with high-energy ions 23. Accordingly, the amount of hydrogen atoms 9 implanted into a gate insulating film 203 is larger than that of the third embodiment. This can degrade the reliability of the n-type MOS transistor.

The method of manufacturing a semiconductor device according to the third embodiment employs the plasma doping on doping impurities into the p-type polycrystalline silicon film 204 as well as employing the plasma doping on doping impurities into the n-type extension regions 210 and n-type source/drain regions 212. Accordingly, the productivity of the semiconductor device 200 can be increased, and the amount of hydrogen atoms implanted into the gate insulating film 203 can be reduced, thus increasing the reliability of the MOS transistor.

The third embodiment is described using the case of forming two types of transistors, n-type and p-type MOS transistors but is not limited to the n-type and p-type MOS transistors. The third embodiment is applicable to the case of introducing different impurities into a cell portion and a peripheral circuit portion in a NAND flash memory, for example. The same method as the first step can be used to form a first impurity layer on a first impurity diffusion region of the cell portion and form a second impurity layer on a second impurity diffusion region of the peripheral circuit portion, for example.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, comprising:
forming an impurity layer containing impurity atoms on a semiconductor layer;
irradiating the impurity layer with first ions having a first energy; and
irradiating the impurity layer with second ions having a second energy larger than the first energy.

2. The method according to claim 1, wherein the impurity layer contains hydrogen atoms in addition to the impurity atoms.

3. The method according to claim 2, wherein at least parts of the hydrogen atoms are separated from the impurity layer by the irradiation with the first ions, and the impurity atoms are introduced into the semiconductor layer by the irradiation of the second ions.

4. The method according to claim 3, wherein the semiconductor layer is an impurity diffusion layer formed in a substrate, and the semiconductor device is an insulating gate field effect transistor.

5. The method according to claim 3, wherein the semiconductor layer is a polycrystalline silicon film constitute a gate electrode and is formed on a substrate via a gate insulating film, and an insulating gate field effective transistor is manufactured as the semiconductor device.

6. A method of manufacturing a semiconductor device, comprising:
forming a first impurity layer on a first impurity diffusion layer formed in a substrate, the first impurity layer containing first impurity atoms of at least one element selected from boron, carbon, phosphor, arsenic, antimony or indium;
irradiating the first impurity layer with first ions having a first energy, the first ions being obtained by exciting atoms of at least one element selected from the group of helium, neon, argon, krypton or xenon;
irradiating the first impurity layer with second ions having a second energy larger than the first energy to introduce the first impurity atoms into the first impurity diffusion layer, the second ions being obtained by exciting atoms of at least one element selected from helium, neon, argon, krypton or xenon;
forming a second impurity layer on a second impurity diffusion layer formed in the substrate, the second impurity layer containing second impurity atoms of at least one element selected from boron, carbon, phosphor, arsenic, antimony or indium;
irradiating the second impurity layer with third ions having a third energy, the third ions being obtained by exciting atoms of at least one element selected from helium, neon, argon, krypton or xenon; and
irradiating the second impurity layer with fourth ions having a fourth energy larger than the third energy to introduce the second impurity atoms into the second impurity diffusion layer, the fourth ions being obtained by exciting atoms of at least one element selected from helium, neon, argon, krypton or xenon.

7. The method according to claim 6, wherein at least one of the first and second impurity layers is formed on the corresponding one of the first and second impurity diffusion layers by plasma doping.

8. The method according to claim 6, wherein the second ions are ions obtained by exciting atoms of the same kind as that the first ions.

9. The method according to claim 6, wherein the formation of the first impurity layer, the irradiation of the first impurity layer with the first ions, and the irradiation of the first impurity layer with the second ions are carried out in the same chamber.

10. The method according to claim 6, further comprising performing heat treatment on at least one of the first and second impurity diffusion layers to activate at least the corresponding first or second impurity atoms.

11. The method according to claim 6, further comprising:
forming a third or fourth impurity layer including third or fourth impurities on the first or second impurity diffusion layers, respectively, the third and fourth impurities containing impurity atoms of the same conductivity types as the first and second impurity atoms, respectively, the third and fourth impurity layers being thicker than the first and second impurity layers, respectively;
irradiating the third or fourth impurity layer with third ions having a third energy; and
irradiating the third or fourth impurity layer with fourth ions having a fourth energy larger than the third energy to introduce the third or fourth impurity atoms deeper than the first or second impurity atoms.

12. A method of manufacturing a semiconductor device, comprising:
forming a semiconductor film to be formed as a gate electrode on a semiconductor substrate via a gate insulating film;
forming a first impurity layer on the semiconductor film, the first impurity layer containing first impurity atoms of at least one element selected from boron, carbon, phosphor, arsenic, antimony or indium;
irradiating the first impurity layer with first ions having a first energy, the first ions being obtained by exciting atoms of at least one element selected from helium, neon, argon, krypton or xenon;
irradiating the first impurity layer with second ions having a second energy larger than the first energy to introduce the first impurity atoms into the semiconductor film, the second ions being obtained by exciting atoms of at least one element selected from helium, neon, argon, krypton or xenon; and
etching the semiconductor film selectively to form the gate electrode.

13. The method according to claim 12, wherein the first impurity layer is formed on the semiconductor film by plasma doping.

14. The method according to claim 12, wherein the second ions are ions obtained by exciting atoms of the same kind as that of the first ions.

15. The method according to claim 12, wherein the formation of the first impurity layer, the irradiation of the first impurity layer with the first ions, and the irradiation of the first impurity layer with the second ions are carried out in the same chamber.
